(19) United States
(12) Patent Application Publication
(10) Pub. No.: US 2010/0084005 A1
(43) Pub. Date: Apr. 8, 2010

(54) SOLAR CELL MODULE

(76) Inventor: Seung-Yeop Myong, Seoul (KR)

Correspondence Address: The Belles Group, P.C., 1518 Walnut Street, Suite 1706, Philadephia, PA, 19102, US

(21) Appl. No.: 12/573,568

(22) Filed: Oct. 5, 2009

(30) Foreign Application Priority Data
Oct. 6, 2008 (KR) 10-2008-0097483

(51) Int. Cl. H01L 31/048

(52) U.S. Cl. 136/251

(57) ABSTRACT

A solar cell module comprises a solar cell panel, a solar cell frame including an insertion groove in which a peripheral portion of the solar cell panel is inserted and a protrusion located within a corner part of the solar cell frame between a rear surface of the solar cell panel and a surface of the insertion groove facing each other.

This application claims the benefit of Korean Patent Application No. 10-2008-97483 filed on Oct. 6, 2008, which is hereby incorporated by reference.

### BACKGROUND

1. Field

The present embodiment relates to a solar cell module.

2. Description of the Related Art

Recently, a solar cell tends to be frequently installed in houses or buildings for environment protection or energy savings. A solar cell module is constructed by packing solar cells so that an output voltage and an output current are increased to a desired value and are used for a long time.

As illustrated in FIG. 1, a conventional solar cell module 1 is installed at a roof of a building, and frames 2 and 3 are installed at a peripheral end of a solar cell panel to support a solar cell 4.

In this case, frames 2 and 3 are manufactured by press molding of a metallic material. After corners of frames 2 and 3 are cut to be tilted to one side at a right angle, they are engaged and fixed with each other. A plurality of solar cells 4 are mounted on a surface of a glass substrate to be electrically connected in series or parallel. Further, a terminal box (not shown) is installed at the rear surface of the glass substrate. The solar cells 4 are coupled with an external electric wire (not shown) using the terminal box. Direct current power generated from solar cells 4 is converted into alternating current power by a separate power converter, which is supplied to a user through a common power path in a building.

Here, in the conventional solar cell module 1, when a material of a solar cell panel is glass, as the size of the solar cell panel is increased, the glass is significantly bent. Due to this, after locking of a solar cell frame, when a solar cell module is mounted, a glass falls on four corners of the solar cell frame, thereby forming a space between the solar cell frame and the solar cell panel. This deteriorates wind pressure resistance and moisture tolerance to the space, and performance of an entire product of the solar cell module. Moreover, the solar cell module has a bad exterior appearance to deteriorate the reliability thereof.

### SUMMARY

In one aspect, a solar cell nodule comprises a solar cell panel, a solar cell frame including an insertion groove in which a peripheral portion of the solar cell panel is inserted and a protrusion located within a corner part of the solar cell frame between a rear surface of the solar cell panel and a surface of the insertion groove facing each other.

In another aspect, a solar cell module comprises a solar cell panel, a solar cell frame including an insertion groove in which a peripheral portion of the solar cell panel is inserted and a plurality of protrusions formed between a rear surface of the solar cell panel and a surface of the insertion groove facing each other.

### BRIEF DESCRIPTION OF THE DRAWINGS

The accompany drawings, which are included to provide a further understanding of the invention and are incorporated on and constitute a part of this specification, illustrate embodiments of the invention and together with the description serve to explain the principles of the invention. In the drawings:

FIG. 1 is a view illustrating a structure of a conventional solar cell module.

FIG. 2 is a rear view illustrating a structure of a solar cell module on which a solar cell frame is mounted in accordance with an embodiment of the present invention;

FIG. 3 is a cross-sectional view illustrating a first frame member of a solar cell frame shown in FIGS. 2; and

FIG. 4 is a cross-sectional view illustrating a structure of a solar cell module shown in FIG. 2.

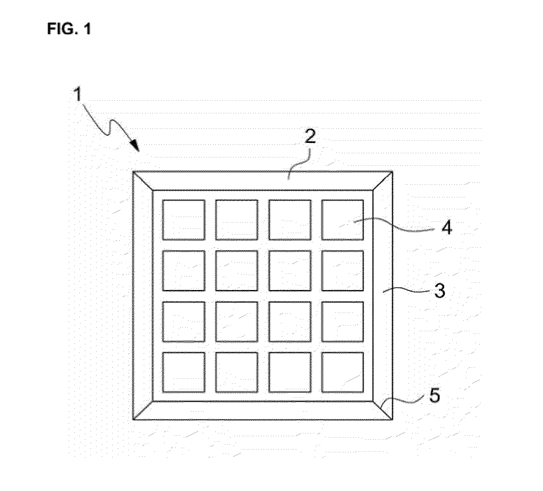

### DETAILED DESCRIPTION OF EMBODIMENTS

Reference will now be made in detail embodiments of the invention examples of which are illustrated in the accompanying drawings.

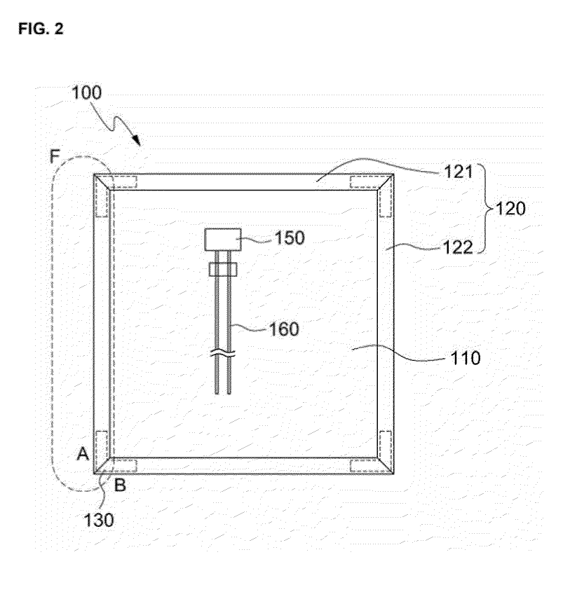

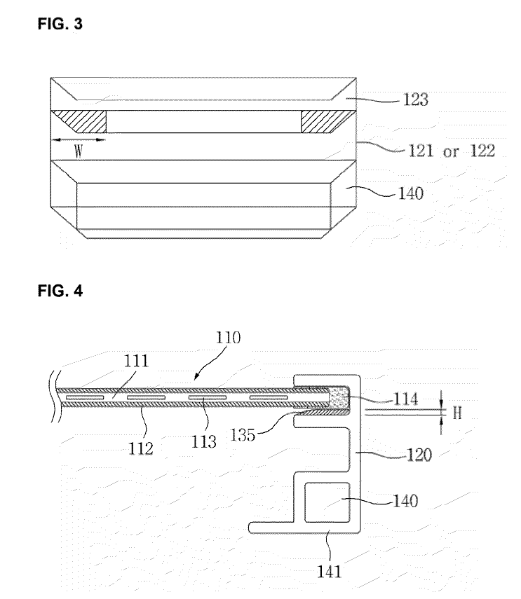

FIG. 2 is a rear view illustrating a structure of a solar cell module with a solar cell frame in accordance with an embodiment of the present invention. FIG. 3 is a cross-sectional view illustrating a first frame member of a solar cell frame shown in FIG. 2. FIG. 4 is a cross-sectional view illustrating a structure of a solar cell module shown in FIG. 2.

FIG. 2 is a rear view illustrating a structure of a solar cell module on which a solar cell frame is mounted in accordance with the present invention.

As shown in FIG. 2, the solar cell module 100 on which a solar cell frame is mounted in accordance with the present invention includes a solar cell panel 110 and solar cell frames 120 and 130. The solar cell frames 120 and 130 are mounted at a peripheral portion of the solar cell panel 110 and fix the solar cell panel 110. Further, the solar cell module 100 further includes a junction box 150 which is adhered on the solar cell panel 110, and is formed by synthetic resin or aluminum metal and the like.

Moreover, the solar cell panel 110 may include a light-transmitting adhesive (refer to FIG. 4) laminated on a plurality of solar cells (refer to FIG. 4), and rear protection materials (refer to FIG. 4) respectively formed on a rear surface of the plurality of solar cells.

For example, a light-transmitting adhesive such as ethylvinyl acetate (EVA) adheres to a plurality of solar cells to be fixed to a light-transmitting substrate including glass or transparent plastic resin. A rear protection material such as a Teflon film, a Poly-Vinyl Fluoride (PVF) film, or a Poly-Ethylen Terephthalate (PET) film is adhered to a rear surface of the light-transmitting adhesive. The rear surface of the light-transmitting adhesive is a non-light receiving surface. In this case, a single crystalline silicon semiconductor, a polycrystalline silicon semiconductor, an amorphous silicon semiconductor, or a chemical semiconductor formed by gallium arsenide and the like may be used as the solar cells. The solar cells can be electrically connected in series.

The junction box 150 is formed by synthetic resin such as ABS resin or aluminum metal, and is adhered on the rear protection material. The junction box 150 transfers output power of the solar cell panel 110 to an outside through a transmission cable 160.

A solar cell frame 120 made by aluminum (Al) and the like is mounted on a peripheral portion of the solar cell panel 110. The solar cell frame 120 alleviates impact applied to the solar cell panel 110 or prevents penetration of foreign substance and the like. Furthermore, when the solar cell module is installed at a building, the solar cell frame 120 is mounted to secure bond strength between an installation member (not shown) and the solar cell panel 110.

The solar cell frame 120 is manufactured by press molding or roll molding. Further, insertion grooves (refer to FIG. 4) are respectively formed at the solar cell frame 120. Each end of peripheral portions of the solar cell panel 110 is inserted in each of the insertion grooves.

Subsequently, in corners of the solar cell panel 110, solar cell frames 121 and 122 cut to be tilted to one side are engaged with each other through a locking means such as corner keys 130, such that the solar cell frame 120 is firmly fixed to an installation member.

Here, the solar cell panel 110 may be formed in square or rectangular shape. However, the present invention is not limited thereto.

Meanwhile, an adhesive, a bolt, or a corner key may be used as the locking means of the solar cell frame. However, in the embodiment of the present invention, it will be described later that a corner key is used as the locking means of the solar cell frame.

As shown in FIG. 2, the solar cell frame 120 includes first frame members 121 formed at horizontal sides of upper and lower portions of the solar cell panel 110, and second frame members 122 at vertical sides of right and left portions of the solar cell panel 110. The first frame members 121 and the second frame members 122 engage with each other in a corner portion of the solar cell panel 110 through a corner key 130. The solar cell frame 120 includes a through hole (refer to FIG. 4) for insertion of the corner key 130. The through hole may be positioned at a lower corner of the solar cell panel 110 with which the solar cell frame 120 engages.

Further, referring to FIG. 4, the solar cell frame 120 includes a protrusion 135 which is located within an insertion groove 123 formed at an edge part of the solar cell frame 120. The protrusion 135 is located between a rear surface of the solar cell panel 110 and a surface of the insertion groove 123 facing each other. Light may not be incident to the rear surface of the solar cell panel 110.

As the size of the solar cell module is increased, a substrate of the solar cell panel such as a glass substrate is significantly bent. For this reason, when the solar cell module 100 is installed at an installation member and the like after engagement of the solar cell panel 110 with the solar cell frame 120, the substrate located at four corner parts of the solar cell frame 120 falls. When the substrate of the solar cell panel 110 falls, since contact of the solar cell panel 100 with the solar cell frame 120 is not completely achieved, a space is formed between the solar cell panel 110 and the solar cell frame 120.

Since the protrusion 135 is located at the solar cell panel 110 and the solar cell frame 120 to prevent the space between solar cell panel 110 and the solar cell frame 120 from being formed, the solar cell panel 110 is stably adhered closely to the solar cell frame 120.

In the meantime, as shown in FIG. 2, the protrusion 135 may be formed in only four corner parts A, B of the solar cell frame 120 in which the solar cell panel 110 is inserted. A plurality of protrusions may be formed in respective parts F of four frame members 121 and 122 constituting horizontal sides and vertical sides of the solar cell frame 120.

Constructions and functions of the solar cell panel and the solar cell frame of the solar cell module as described above in accordance with the present invention may be described in detail with reference to FIG. 3 and FIG. 4.

FIG. 3 is a cross-sectional view illustrating a first frame member 121 of a solar cell frame shown in FIG. 2. FIG. 4 is a cross-sectional view illustrating a structure of a solar cell module shown in FIG. 2.

Referring to FIG. 3 and FIG. 4, the solar cell module 110 in accordance with an embodiment of the present invention includes a solar cell frame 120 installed at a peripheral portion of the solar cell panel 110.

The solar cell panel 110 includes a plurality of solar cells 113. Each of the solar cells 113 includes a transparent electrode layer (not shown) formed on a substrate (not shown), a photoelectric conversion layer (not shown) and a rear electrode layer (not shown) sequentially formed on the transparent electrode layer. The plurality of solar cells 113 are electrically connected to each other in series. The solar cell panel 110 may include a light-transmitting adhesive 111 laminated on the plurality of solar cells 113, and rear protection materials 112 located opposite to an incident direction of light.

The solar cell frame 120 car be made by aluminum (Al). That is, the solar cell frame 120 may be achieved by high strength aluminum. The solar cell panel 110 is inserted in a frame member of aluminum alloy having high mechanical strength and fixed in the solar cell frame 120.

The solar cell frame 120 may include a first frame member 121 and a second frame member 122, which are engaged with each other by a corner key 130. The first frame members 121 may be provided at horizontal sides of upper and lower portions of the solar cell panel 110. The second frame members 122 may be provided at vertical sides of right and left portions of the solar cell panel 110.

Moreover, insertion grooves 123 are formed at upper portions of the first frame member 121 and the second frame member 122. In this case, a peripheral side of the solar cell panel 100 is inserted in the insertion grooves 123. A shape of each of the insertion grooves 123 may correspond to that of a peripheral side of the solar cell panel 110 so that the peripheral side of the solar cell panel 100 can be inserted in the insertion grooves 123. A space between the solar cell panel 110 inserted in the insertion grooves 123 and the solar cell frame 120 may be filled with a filler 114 to prevent penetration of moisture and steam.

A through hole 140 is formed at a lower portion of the solar cell frame 120 such that a corner key is inserted therein. Insertion of the corner key 130 in the through hole 140 causes the first frame member 121 and the second frame member 122 to be engaged with each other. Here, the through hole 140 is not limited to a special shape. That is, the shape of the through hole 140 may be formed corresponding to a shape of the corner key 130 so that the corner key is inserted therein.

In addition, the protrusion 135 may be located in the insertion groove 123 formed at a corner part of the solar cell frame 120. The protrusion 135 is formed between a rear surface of the solar cell panel 110 and a surface of the insertion groove 123 facing each other. In this case, the protrusion 135 may be formed upon manufacturing the solar cell panel 110 using a metallic pattern.

Namely, when the solar cell panel 110 includes a glass substrate, as the size of the solar cell module 100 is increased, the glass substrate is significantly bent. After the solar cell panel 100 is mounted on the solar cell frame 120, when the solar cell module 100 is installed, four corner parts of a glass of the solar cell panel 110 fall, thereby forming a space between the solar cell panel 110 and the solar cell panel 120.

Since the protrusion 135 is located between the rear surface of the solar cell panel 110 and the surface of the insertion groove 123 facing each other, it prevents formation of the space between the solar cell panel 110 and the solar cell frame 120.

A height H of the protrusion 135 may range from 1 mm to 3 mm from a surface of the insertion groove 123. If the height H of the protrusion 135 is less than 1 mm, a space may be formed between the solar cell panel 110 and a surface of the insertion groove 123 to bend the glass substrate of the solar cell panel 110. Accordingly, a glass substrate or a sealing member of a glass material can be damaged and efficiency of the solar cell module 100 can be deteriorated. Meanwhile, if the height H of the protrusion 135 is greater than 3 mm, because it is difficult to insert the solar cell panel 110 in the insertion groove 123, the solar cell module 100 may have difficulty in being assembled.

In addition, a length W of the protrusion 135 may be in a range from 3% to 8% of that of a horizontal side or a vertical side of the solar cell panel 110. If the length W of the protrusion 135, that is, an axial length of the solar cell frame 120 is less than 3% of the length of the horizontal side or the vertical side of the solar cell panel 110, a space is formed between the solar cell frame and the solar cell panel, thereby bending the glass substrate. This may damage the solar cell panel 110 or a sealing member of glass material. Further, if bending of the solar cell panel 110 is increased, efficiency of the solar cell panel 110 can be deteriorated. Meanwhile, if the length W of the protrusion 135 is greater than 8% of the length of the horizontal side or the vertical side of the solar cell panel 110, a manufacturing cost of the solar cell frame 120 is increased.

An end of the protrusion 13E is rounded to a curved shape. This may prevent a glass from being broken in corner parts of the solar cell panel 110 upon locking of the solar cell frame 120 with the solar cell panel 110, and may prevent a sealing part of a glass side from being damaged.

Consequently, the protrusion 135 of the solar cell module 100 may prevent the solar cell panel 110 from being bent. After locking of a solar cell frame, when a solar cell module 100 is mounted, a glass falls on corner parts of the solar cell panel 110, thereby forming a space between the solar cell panel 110 and the solar cell frame 120. In this case, the protrusion 135 may prevent the space from being formed between the solar cell panel 110 and the solar cell frame 120. In addition, since an exterior appearance of the solar cell module 100 becomes firm, the reliability of the solar cell module may be improved.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A solar cell module comprising:
a solar cell panel;
a solar cell frame including an insertion groove in which a peripheral portion of the solar cell panel is inserted; and
a protrusion located within a corner part of the solar cell frame between a rear surface of the solar cell panel and a surface of the insertion groove facing each other.

2. The solar cell module according to claim 1, wherein a height of the protrusion ranges from 1 mm to 3 mm from a surface of the insertion groove.

3. The solar cell module according to claim 1, wherein a length of the protrusion is in a range from 3% to 8% of that of a horizontal side or a vertical side of the solar cell panel.

4. The solar cell module according to claim 1, wherein an end of the protrusion is curve-shaped.

5. The solar cell module according to claim 1, wherein the solar cell frame is formed by aluminum.

6. A solar cell module comprising:
a solar cell panel;
a solar cell frame including an insertion groove in which a peripheral portion of the solar cell panel is inserted; and
a plurality of protrusions formed between a rear surface of the solar cell panel and a surface of the insertion groove facing each other.

7. The solar cell module according to claim 6, wherein a height of each of the plurality of protrusions ranges from 1 mm to 3 mm from a surface of the insertion groove.

8. The solar cell module according to claim 6, wherein a length of each of the plurality of protrusions is in a range from 3% to 8% of that of a horizontal side or a vertical side of the solar cell panel.

9. The solar cell module according to claim 6, wherein an end of each of the plurality of protrusions is curve-shaped.

10. The solar cell module according to claim 6, wherein the solar cell frame is formed by aluminum.
